(19) United States
(12) Patent Application Publication
(10) Pub. No.: US 2013/0244175 A1
(43) Pub. Date: Sep. 19, 2013

(54) LITHOGRAPHIC PRINTING PLATE PRECURSORS AND METHODS OF USE

(71) Applicants: Eynat Matzner, Adi (IL); Anna Sigalov, Natanya (IL)

(72) Inventors: Eynat Matzner, Adi (IL); Anna Sigalov, Natanya (IL)

(21) Appl. No.: 13/420,713

(22) Filed: Mar. 15, 2012

(51) Int. Cl. G03F 7/20; G03F 7/004

(52) U.S. Cl. 430/280.1; 430/302

(57) ABSTRACT

Lithographic printing plates are prepared from lithographic printing plate precursors that have an imageable layer comprising hydrophobic thermosetting particles that comprise a curable composition having certain properties. Upon exposure to imaging radiation such as infrared radiation, the hydrophobic thermosetting particles are cured and fused to each other and to the substrate. Such particles can be readily removed in the non-exposed regions of the imageable layer by dry rubbing or other simple processes without the use of alkaline developers or gumming solutions.

### FIELD OF THE INVENTION

This invention relates to lithographic printing plate precursors and methods for using them to prepare lithographic printing plates having imageable layers comprising hydrophobic thermosetting polymeric particles.

### BACKGROUND OF THE INVENTION

Recent trends in the preparation of printing plates for offset lithographic printing generally include forming lithographic printing plates from lithographic printing plate precursors using digital information from a computer for producing final copy printed output on a printing press. This process is known as Computer-to-Plate (CTP). Infrared lasers are used for transferring the digital information in the form of an image from the computer to the lithographic printing plate precursor. The imaging process can be sped up if precursor sensitivity is increased. There is also a desire to simplify lithographic printing plate preparation after imaging, to make it more environmentally friendly and also to reduce the number of steps and the extent of operation handling.

Lithographic printing plates have been prepared by laser ablation of imageable layers in lithographic printing plate precursors, for examples as described in U.S. Pat. No. 5,339,737 (Lewis et al.). While this process minimizes the need for post-imaging treatment of the printing plates, the decomposition products from laser ablation must be captured in some manner and this creates a potential environmental problem if the debris escapes into the atmosphere. In addition, the energy needed for this process is generally much higher than for conventional imaging that is followed by wet processing. There is a desire to avoid the need for wet processing using known alkaline solutions that must be disposed of into the sewer and require expensive processing apparatus and manual upkeep such as cleaning.

One way to avoid use of the highly alkaline processing solutions is to use acidic or more neutral processing solutions. To stop development before it proceeds too long, the lithographic printing plates are generally rinsed with water. However, the acid nature of a fountain solution used in a printing press will tend to cause further printing plate development and consequently such printing plates can have a shorter printing run length.

Other attempts to avoid wet processing involve the use of a non-film-forming polymer emulsion that is mixed with an energy absorbing material such as carbon black, as described for example in U.S. Pat. No. 4,731,317 (Fromson et al.). In such embodiments, laser energy described as fusing the polymer emulsion particles to the substrate. A surfactant solution is described for development.

U.S. Pat. No. 6,357,353 (Vermeersch) discloses a method of making lithographic printing plate precursors by applying a dry powder containing infrared radiation absorber and a thermoplastic polymer that can be in the form of microcapsules. The dry powder is rubbed into the hydrophilic surface of the lithographic printing plate precursor and imaging is said to cause the powder to adhere to the substrate. The non-imaged (non-exposed) areas are described as being washed away with water. The thermoplastic polymers tend to be vulnerable to damage from solvents used in the offset litho printing process, and long print runs would not be expected.

Similarly, U.S. Pat. No. 6,244,181 (Leenders et al.) describes the use of a dry powder having a very high amount of IR absorber, and U.S. Pat. No. 6,550,387 (Vermeersch et al.) describes fusing small thermoplastic polymeric particles during imaging to form lithographic printing plates. Melting powders are also described in EP 099,264A2 (Doyle).

There remains a need for lithographic printing plate precursors that can be readily imaged using laser ablation but which require minimal or no wet processing using conventional alkaline solutions, and from which lithographic printing plates can be prepared having desired run length.

### SUMMARY OF THE INVENTION

This invention provides a lithographic printing plate precursor that is sensitive to infrared radiation, the lithographic printing plate precursor comprising:

a hydrophilic substrate,

an imageable layer disposed over the hydrophilic substrate, and

optionally a hydrophilic layer disposed over the hydrophilic substrate and under the imageable layer,

the imageable layer consisting essentially of hydrophobic thermosetting particles that comprise: (1) a curable composition that has a softening point of at least 50° C. and up to and including 120° C. as determined by ASTM D6493, and a curing temperature of at least 150° C. and up to and including 250° C. as determined by Differential Scanning Calorimetry (DSC) at a heating rate of 10° C./minute, and optionally (2) one or more pigments in an amount of less than 30 weight % based on the total dry weight of the hydrophobic thermosetting particles,

wherein the curable composition comprises a polymerizable oligomer comprising one or more epoxy, hydroxy, carboxy, or amino groups, and

wherein prior to infrared radiation exposure:
(a) the hydrophobic thermosetting particles adhere to each other and to the substrate such that at least 65 weight % of the hydrophobic thermosetting particles are retained on the substrate when subjected to an air blowing test,
(b) at least 80 weight % of the hydrophobic thermosetting particles can be removed from the imageable layer by dry rubbing using a dry woven cloth having at least 90% cotton in the direction of the graining with manual pressure for 30 seconds, and
(c) the hydrophobic thermosetting particles have an average diameter of at least 1 μm.

Some embodiments of this invention relates to a lithographic printing plate precursor that is sensitive to infrared radiation, the lithographic printing plate precursor comprising:

a hydrophilic aluminum-containing substrate,

an imageable layer disposed over the hydrophilic substrate, and

optionally a hydrophilic layer disposed over the hydrophilic aluminum-containing substrate and under the imageable layer,

the imageable layer consisting essentially of hydrophobic thermosetting particles that comprise: (1) a curable composition that has a softening point of at least 50° C. and up to and including 80° C. as determined by ASTM D6493, and a curing temperature of at least 150° C. and up to and including 200° C. as determined by Differential Scanning Calorimetry (DSC) at a heating rate of 10° C./minute, and (2) a carbon black in an amount of at least 0.1 weight % and up to and including 20 weight % based on the total dry weight of the hydrophobic thermosetting particles,

wherein the curable composition comprises a polymerizable oligomer selected from the group consisting of acrylic oligomers, epoxy-containing prepolymers, amino-modified epoxy oligomers, phenolic-modified epoxy oligomers, and a polyol with an isocyanate-containing oligomer, and the curable composition also comprises a curing agent for the curable composition,

the imageable layer containing less than 5 weight % of film-forming binder polymers,

wherein prior to infrared radiation exposure:
(a) the hydrophobic thermosetting particles adhere to each other and to the substrate such that at least 80 weight % of the hydrophobic thermosetting particles are retained on the substrate when subjected to an air blowing test,
(b) at least 90 weight % of the hydrophobic thermosetting particles can be removed from the imageable layer by dry rubbing (for example, using a dry woven cloth having at least 90% cotton in the direction of the graining using manual pressure for 30 seconds), and
(c) the hydrophobic thermosetting particles have an average diameter of at least 1 μm and up to and including 10 μm.

Moreover, this invention further provides a method of making a lithographic printing plate, the method comprising:

imagewise exposing the lithographic printing plate precursor of this invention (such as those described in this Summary of the Invention) to infrared radiation, to create exposed and non-exposed regions in the imageable layer, and

removing the hydrophobic thermosetting particles in the non-exposed regions of the imageable layer.

This invention also provides a method of preparing a lithographic printing plate precursor, comprising:

applying a suspension of hydrophobic thermosetting particles over a hydrophilic substrate, the hydrophobic thermosetting particles comprising: (1) a curable composition that has a softening point of at least 50° C. and up to and including 120° C. as determined by ASTM D6493, and a curing temperature of at least 150° C. and up to and including 250° C. as determined by Differential Scanning Calorimetry (DSC) at a heating rate of 10° C./minute, and optionally (2) one or more pigments in an amount of less than 30 weight % based on the total dry weight of the hydrophobic thermosetting particles,

wherein the curable composition comprises a polymerizable oligomer comprising one or more epoxy, hydroxy, carboxy, or amino groups, and

wherein prior to infrared radiation exposure:
(a) the hydrophobic thermosetting particles adhere to each other and to the substrate such that at least 65 weight % of the hydrophobic thermosetting particles are retained on the substrate when subjected to an air blowing test,
(b) at least 80 weight % of the hydrophobic thermosetting particles can be removed from the imageable layer by dry rubbing using a dry woven cloth having at least 90% cotton in the direction of the graining using manual pressure for 30 seconds, and
(c) the hydrophobic thermosetting particles have an average diameter of at least 1 μm,

optionally applying a hydrophilic layer formulation over the substrate to form a hydrophilic layer prior to applying the suspension of hydrophobic thermosetting particles over the hydrophilic layer, and

drying the suspension of hydrophobic thermosetting particles to form a dried imageable layer on the hydrophilic substrate.

There are numerous advantages provided by this invention. The lithographic printing plate precursors of this invention are sufficiently safe for transportation and handling by the customer both before and after imaging without damage but which can be easily “developed” after imaging without conventional alkali developers.

The “powder” (suspension of hydrophobic thermosetting particles) deposited over the substrate as an imageable layer during manufacture can be applied without the need for film-forming binder polymers. A non-polymeric curable composition with certain properties is included within the imageable layer so that energy from imaging can form a polymeric matrix that adequately adheres to the substrate surface (or layers applied over the substrate) as well as forming an oleophilic image. Yet, non-imaged regions of the imageable layer can be readily removed by dry rubbing (as defined below).

Thus, during the formation of lithographic printing plates, an image is formed upon heating with a suitable laser such as an infrared radiation laser. The imaged regions are cured or crosslinked either by the imaging energy or by an additional energy source (post-imaging heating). Such curing and crosslinking provides good resistance to printing press chemistries and longer run length during printing.

It is an important advantage that the non-imaged regions of the deposited powder are easily removable by dry cleaning (for example, wiping or rubbing with a dry woven cloth) or by use of minimal liquid in a damp cloth or roller. In some embodiments, the non-imaged regions can be removed on-press using lithographic printing inks, fountain solutions, or both lithographic printing inks and fountain solutions.

In some embodiments, a thin hydrophilic coating can be applied to the substrate before application of the suspension of hydrophobic thermosetting particles to form the imageable layer. This hydrophilic coating can be applied in order to avoid a gumming step after imaging and to promote dry cleaning of the imaged precursor with the need for additional chemicals.

These advantages are achieved by incorporating an imageable layer that comprises hydrophobic thermosetting particles that comprise the curable composition described herein, and one or more pigments (such as a carbon black) in an amount of less than 30 weight %. The curable composition comprises one or more polymerizable oligomers (described below). During imaging, the hydrophobic thermosetting particles are cured (or polymerized) so that they are adhered strongly to the hydrophilic substrate (or underlying hydrophilic layers). The hydrophobic thermosetting polymeric particles in the non-exposed regions can be removed off-press without the use of an alkali processing solution or gumming solution.

### DETAILED DESCRIPTION OF THE INVENTION

### Definitions

As used herein to define various components of the lithographic printing plate precursors, imageable layers, and hydrophilic layers, unless otherwise indicated, the singular forms “a”, “an”, and “the” are intended to include one or more of the components (that is, including plurality referents).

Each term that is not explicitly defined in the present application is to be understood to have a meaning that is commonly accepted by those skilled in the art. If the construction of a term would render it meaningless or essentially meaningless in its context, the term's definition should be taken from a standard dictionary.

The use of numerical values in the various ranges specified herein, unless otherwise expressly indicated otherwise, are considered to be approximations as though the minimum and maximum values within the stated ranges were both preceded by the word “about”. In this manner, slight variations above and below the stated ranges can be used to achieve substantially the same results as the values within the ranges. In addition, the disclosure of these ranges is intended as a continuous range including every value between the minimum and maximum values.

Unless the context indicates otherwise, when used herein, the terms “lithographic printing plate precursor”, “printing plate precursor”, and “precursor” are meant to be references to embodiments of the present invention.

Moreover, unless otherwise indicated, percentages refer to percents by total dry weight, for example, weight % based on total solids of either an imageable layer or hydrophilic layer, or formulations used to make those layers. Unless otherwise indicated, the percentages can be the same for either the dry imageable layer or the total solids of the formulation used to make that layer.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

The term “polymer” refers to high and low molecular weight polymers including oligomers and includes homopolymers and copolymers.

The term “copolymer” refers to polymers that are derived from two or more different monomers.

The term “backbone” refers to the chain of atoms (carbon or heteroatoms) in a polymer to which a plurality of pendant groups are attached. One example of such a backbone is an “all carbon” backbone obtained from the polymerization of one or more ethylenically unsaturated polymerizable monomers. However, other backbones can include heteroatoms wherein the polymer is formed by a condensation reaction or some other means.

The term “polymerizable oligomer” also includes polymerizable prepolymers that can have one more polymerizable sites in the molecule but generally have a molecular weight of less than 2,000 as determined by gel permeation chromatography (GPC) whereas polymers have a higher molecular weight.

The “air blowing test” used herein to define the adhesion of the hydrophobic thermosetting particles prior to infrared radiation exposure is carried out using a commonly available 2000 watt blow dryer (for example, a Bosch GHG 630 DCE blow dryer, Speed 1) using a shot of air at 25-30° C. for 1 minute. The loss of material can be evaluated by observing the decrease in optical density before and after the air blowing test is carried out, for example by using a 500 Series Spectro densitometer available from X-Rite, Inc. on color mode visible.

As used herein, “dry rubbing” refers to rubbing the applied hydrophobic thermosetting particles on the substrate using a dry woven cloth comprised of at least 90% cotton (or typically 100% cotton) in the direction of the graining of the aluminum-containing substrate using manual pressure for 30 seconds. The loss in material from the dry rubbing can be evaluated by measuring the decrease in optical density before and after the dry rubbing test is carried out, for example by using a 500 Series Spectro densitometer available from X-Rite, Inc. on color mode visible.

### Substrates

The essential and optional layers described herein for the lithographic printing plate precursors are generally disposed on a suitable hydrophilic substrate that is generally not purposely electrically charged for manufacture or use of the precursors.

The hydrophilic substrate used to prepare the lithographic printing plate precursors used in this invention comprises a support that can be composed of any material that is conventionally used to prepare lithographic printing plates and has a hydrophilic surface on the substrate imaging side. The hydrophilic substrate is usually in the form of a sheet, film, or foil (or web), and is strong, stable, and flexible and resistant to dimensional change under conditions of use. Typically, the hydrophilic substrate can comprise any self-supporting material including polymeric films (such as polyester, polyethylene, polycarbonate, cellulose ester polymer, and polystyrene films), glass, ceramics, metal sheets or foils, or stiff papers (including resin-coated and metalized papers), or a lamination of any of these materials (such as a lamination of an aluminum foil onto a polyester film). Metal supports include sheets or foils of aluminum, copper, zinc, titanium, and alloys thereof.

One useful hydrophilic substrate is composed of an aluminum support that can be treated using techniques known in the art, including roughening of some type by physical (mechanical) graining, electrochemical graining, or chemical graining, usually followed by acid anodizing. The aluminum support can be roughened by physical or electrochemical graining and then anodized using phosphoric or sulfuric acid and conventional procedures. A useful hydrophilic lithographic substrate is an electrochemically grained and sulfuric acid or phosphoric acid anodized aluminum support that provides a hydrophilic surface for lithographic printing.

Sulfuric acid anodization of the aluminum support generally provides an oxide weight (coverage) on the surface of at least 1.5 g/m² and up to and including 5 g/m². Phosphoric acid anodization generally provides an oxide weight on the surface of at least 1 g/m² and up to and including 5 g/m².

The aluminum-containing support can also be treated with, for example, a silicate, dextrin, calcium zirconium fluoride, hexafluorosilicic acid, poly(vinyl phosphonic acid) (PVPA), vinyl phosphonic acid copolymer, poly[(meth)acrylic acid], or acrylic acid copolymer to increase hydrophilicity. Still further, the aluminum support can be treated with a phosphate solution that can further contain an inorganic fluoride (PF).

The thickness of the hydrophilic substrate can be varied but should be sufficient to sustain the wear from printing and thin enough to wrap around a printing form. Useful embodiments include a treated aluminum foil having a thickness of at least 100 μm and up to and including 700 μm.

### Hydrophilic Layer

In some embodiments, an additional hydrophilic layer is disposed over (for example, directly on) the hydrophilic substrate and the imageable layer is disposed over (for example, directly on) this hydrophilic layer. Thus, for many embodiments, the lithographic printing plate precursor consists of the hydrophilic substrate having thereon (in order from a hydrophilic substrate such as a hydrophilic aluminum-containing substrate), a hydrophilic layer and an imageable layer (described below).

The presence of this hydrophilic layer can enhance processing of the imaged lithographic printing plate precursor without the use of the usual alkaline processing solutions (developers).

Useful components of the hydrophilic layer include but are not limited to, hydrophilic polymers, silanes (such as vinyl silane), and fillers (such as silica particles).

The hydrophilic layer can be provided at a dry coverage of at least 0.3 g/m² and up to and including 2 g/m², or typically of at least 0.5 g/m² and up to and including 1.5 g/m². The dry thickness of this hydrophilic layer can be at least 0.3 μm and up to and including 2 μm and typically at least 0.5 μm and up to and including 1.5 μm.

### Imageable Layer

The imageable layer is disposed over the hydrophilic substrate and is used to provide an image upon exposure to infrared radiation that creates both exposed and non-exposed regions in this imageable layer. The imageable layer consists essentially of “thermosetting” particles as opposed to thermoplastic (or elastomeric) particles as those terms are known in the art. These particles are also considered “hydrophobic”, meaning that they do not dissolve in water. Besides the one or more pigments described below, there are no other components in the imageable layer that are essential to the imaging function of the precursors. In particular, there are no film-forming binders purposely incorporated into the imageable layer.

Before imagewise exposure of the lithographic printing plate precursor to the infrared radiation, the hydrophobic thermosetting particles in the imageable layer have several properties:
(a) The hydrophobic thermosetting particles adhere to each other when they are in contact with each other and to the substrate on which they are disposed in a suitable manner. At least 75 weight % (typically at least 90 weight %) of the hydrophobic thermosetting particles are retained on the substrate when subjected to the air blowing test (described above).
(b) At least 80 weight %, and typically at least 90 weight %, of the hydrophobic thermosetting particles can be removed from the imageable layer by dry rubbing (defined above).
(c) The hydrophobic thermosetting particles generally have an average diameter (or largest dimension) of at least 1 μm and up to and including 20 μm, or an average diameter of at least 1 μm and up to and including 10 μm, or even an average diameter of at least 1 μm and up to and including 5 μm. The average diameter can be determined by standards techniques and equipment, for example by evaluating electron micrograph images. The term “average diameter” generally means the largest dimension of particles that are generally spherical but the particles need not be perfectly spherical to be used in this invention. In a suitable solvent such as water, the hydrophobic thermosetting particles form “suspensions” rather than emulsions. They are not likely to settle after 24 hours at room temperature. After infrared radiation exposure, the hydrophobic thermosetting particles may shrink and thus, the size parameter described herein is prior to the imagewise exposure with infrared radiation.

In some embodiments, the hydrophobic thermosetting particles can have a weight average molecular weight below 2,000 as determined by gel permeation chromatography (GPC).

All of the hydrophobic thermosetting particles comprise:
(1) A curable composition that has a softening point of at least 70° C. and up to and including 120° C., typically at least 50° C. and up to and including 80° C., as determined by ASTM D6493, and a curing temperature of at least 150° C. and up to and including 250° C., typically at least 150° C. and up to and including 200° C., as determined by Differential Scanning Calorimetry (DSC) at a heating rate of 10° C./minute. Thus, the curable composition is a solid at room temperature.
(2) Optionally, but preferably, one or more pigments in the amount of less than 30 weight %, and typically at least 0.1 weight % and up to and including 20 weight %, based on the total dry weight of the hydrophobic thermosetting particles. Such pigments are generally infrared radiation absorbers as described in more detail below.

The curable composition comprises one or more polymerizable oligomers that can be cured using free radical chemistry. Such compounds generally comprise one or more reactive epoxy, hydroxy, carboxy, or amino groups in the molecule. For example, useful oligomers can be prepared to comprise epoxy groups from the reaction of epichlorohydrin with a phenol (such as bisphenol A). In general, useful polymerizable (or curable) oligomers include but are not limited to, di- and polyfunctional carboxylic acids, dicyanodiamides, phenolic compounds, amino compounds, and isocyanates. Particularly useful polymerizable oligomers are selected from the group consisting of acrylic oligomers, epoxy-containing prepolymers, amino-modified epoxy oligomers, phenolic-modified epoxy oligomers, and combinations of a polyol with an isocyanate-containing oligomer.

These curable materials can be obtained from various commercial sources and are well known to polymer chemists. The polymerizable oligomers are generally present in the hydrophobic thermosetting particles in an amount of at least 2 weight % and up to and including 65 weight %, or typically in an amount of at least 8 weight % and up to and including 30 weight % based on the total dry particle weight. Upon curing, these materials are polymerized (and possibly crosslinked) to form various thermosetting polymers in the hydrophobic thermosetting particles.

A curing agent or hardening agent can be present in the curable composition of the hydrophobic thermosetting particles to enhance curing of the polymerizable oligomers(s) by reaction with the various reactive groups in the polymerizable oligomers. Useful curing agents or hardening agents include but are not limited to, epoxy or hydroxy alkyl amide curing agents, dimerized isocyanates, dicyanodiamide curing agents, carboxylic acid curing agents, phenolic curing agents, and others known in the art, for example dicyanodiamide, aromatic amines, and aliphatic diamines. The curing or hardening agent is generally present in an amount of at least 1 weight % and up to and including 10 weight %, and typically at least 1.5 weight % and up to and including 5 weight %, based on the weight of the hydrophobic thermosetting particles.

In most embodiments, the hydrophobic thermosetting particles also comprise one or more pigments that are infrared radiation absorbers that generally has a λₘₐₓ of at least 700 nm and up to and including 1500 nm, or typically of at least 750 nm and up to and including 1400 nm. A wide range of useful infrared radiation absorbers include but are not limited to, carbon blacks and other IR radiation absorbing organic or inorganic pigments (including squarylium, cyanine, merocyanine, indolizine, pyrylium, metal phthalocyanines, and metal dithiolene pigments), and metal oxides.

Examples of useful carbon blacks include RAVEN® 450, RAVEN® 760 ULTRA®, RAVEN® 890, RAVEN® 1020, RAVEN® 1250 and others that are available from Columbian Chemicals Co. (Atlanta, Ga.) as well as N 293, N 330, N 375, and N 772 that are available from Evonik Industries AG (Switzerland) and Mogul® L, Mogul® E, Emperor 2000, and Regal® 330, and 400, that are available from Cabot Corporation (Boston Mass.). Both non-conductive and conductive carbon blacks (described below) are useful. Some conductive carbon blacks are described for example in U.S. Pat. No. 7,223,524 (Hiller et al.) that is incorporated herein by reference. Useful conductive carbon blacks also can be obtained commercially as Ensaco™ 150 P (from Timcal Graphite and Carbon), Hi Black 160 B (from Korean Carbon Black Co. Ltd.), and also include those described in U.S. Pat. No. 7,223,524 (noted above, Col. 4, lines 60-62) that is incorporated herein by reference. Useful carbon blacks also include those that are surface-functionalized with solubilizing groups, and carbon blacks that are grafted to hydrophilic, nonionic polymers, such as FX-GE-003 (manufactured by Nippon Shokubai).

Other useful infrared radiation absorbing pigments include, but are not limited to, Heliogen Green, Nigrosine Base, iron (III) oxides, transparent iron oxides, magnetic pigments, manganese oxide, Prussian Blue, and Paris Blue. Still other useful infrared radiation absorbers include carbon nanotubes, such as single- and multi-walled carbon nanotubes, graphite (including porous graphite), graphene, graphite oxide, and carbon fibers. A carbon black is most useful.

The pigments (such as infrared radiation absorbers such as a carbon black) are generally present in the hydrophobic thermosetting particles in an amount of at least 0.1 weight % but less than 30 weight %, or typically at least 0.1 weight % and up to and including 20 weight %, based on the total dry weight of the hydrophobic thermosetting particles.

In some embodiments, the imageable layer comprises an infrared radiation absorber that is outside of the hydrophobic thermosetting particles, but in most embodiments, there are no infrared radiation absorbers are only in these hydrophobic thermosetting particles. When this additional infrared radiation absorber is present both inside and outside the hydrophobic thermosetting particles, it can be the same or different material both inside and outside the hydrophobic thermosetting particles. In most of these embodiments, the same carbon black is inside and outside the hydrophobic thermosetting particles.

The hydrophobic thermosetting particles also comprise non-essential components such as non-infrared radiation absorbing fillers, pigments, extenders, coating aids, and other additives that would be readily apparent to a skilled worker. The amounts of these non-essential components can be less than 10 weight % of the total dry hydrophobic thermosetting particle weight.

Alternatively, such non-essential additives can be mixed with the hydrophobic thermosetting particles in the imageable layer but these are not preferred embodiments. As noted above, the imageable layer is essentially free of film-forming polymeric binders. This means that such materials are not purposely incorporated and comprise less than 5 weight % of the total imageable layer dry weight.

The components of the imageable layer can be formulated and mixed together prior to their application to a substrate using known formulating procedures. Alternatively, the hydrophobic thermosetting particles can be purchased as an already-formulated powder comprising polymerizable oligomers(s) and an infrared radiation absorber such as carbon black, for example as a Fusion Bonded Epoxy powder (available from various commercial sources), and then mixed with any other desirable components.

Additional details of specific commercial hydrophobic thermosetting particles (“powders”) are described for example in US 2008/0103224 (Decker et al.) that is incorporated herein by reference.

The dry coverage of the imageable layer can be at least 2 g/m² and up to and including 20 g/m² or typically of at least 2 g/m² and up to and including 10 g/m². Such coverage typically provides a dry average thickness of at least 2 μm and up to and including 20 which thickness can be determined by measuring at least ten different places within a 5 cm² area of a dried imageable layer using known techniques such as scanning electron micrographs, and taking the average of the measurements.

### Preparation of Lithographic Printing Plate Precursors

If a hydrophilic layer is to be included in a lithographic printing plate precursor, its components can be mixed or dispersed in water and applied as a hydrophilic layer formulation (or aqueous suspension) over the hydrophilic substrate (for example an aluminum-containing substrate) using any suitable coating apparatus and conditions to be located between the substrate and the imageable layer. Once applied, the hydrophilic layer coating can be dried in a suitable manner to remove solvent and to provide a hydrophilic layer having a desired dry coverage described above. The suspension of hydrophobic thermosetting particles can be an aqueous suspension that comprises less than 5 weight % of a water-soluble or water-dispersible binder.

The imageable layer can be formed by applying an appropriate formulation (for example a suspension of hydrophobic thermosetting polymeric particles comprising the curable composition, optional infrared radiation absorber, and optional non-essential addenda) over the hydrophilic substrate (or over the hydrophilic layer if present) and dried to remove solvent in a suitable manner (for example at from 55° C. to 85° C. for at least 30 seconds and up to 5 minutes) to form a dry imageable layer on the hydrophilic substrate. In most embodiments, the suspension solvent is water or predominantly water (more than 50 weight % of total solvents). In some embodiments, the imageable layer formulation can be applied in a dry form without a carrier solvent, but this is not preferred.

During drying of the imageable layer formulation, the hydrophobic thermosetting particles are loosely adhered to the underlying hydrophilic substrate (or hydrophilic layer). Further heating of the applied imageable layer formulation causes curing in the curable composition that can cause surface melting of the hydrophobic thermosetting particles to further adhere them to the hydrophilic substrate and to each other so the precursors can be readily handled, packed, and shipped to the end user with minimal damage. However, the adhesion to the hydrophilic substrate of the hydrophobic thermosetting particles is sufficiently low that at least 80% (or typically at least 90%) of the particles can be removed using the rubbing test as described herein.

### Imaging and Processing

Representative imaging and processing conditions and techniques are demonstrated below in the examples. In general, the lithographic printing plate precursor is imagewise exposed to suitable source of near-infrared or infrared radiation depending upon the specific sensitivity of the imageable layer (that is, the pigments or infrared radiation absorbers incorporate therein), that is at a wavelength (λₘₐₓ) of at least 700 nm and up to and including 1500 nm, or of at least 750 nm and up to and including 1400 nm, or more typically of at least 750 nm and up to and including 1250 nm.

For example, imaging can be carried out using imaging or exposing infrared radiation from an infrared laser (or array of lasers) at a wavelength of at least 750 nm and up to and including about 1400 nm or typically of at least 750 nm and up to and including 1250 nm. Imaging also can be carried out using imaging infrared radiation at multiple wavelengths at the same time, or sequentially, if desired.

The laser used to expose the lithographic printing plate precursor is usually a diode laser, because of the reliability and low maintenance of diode laser systems, but other lasers such as gas or solid-state lasers can also be used. The combination of power, intensity and exposure time for laser imaging would be readily apparent to one skilled in the art. Presently, high performance lasers or laser diodes used in commercially available imagesetters emit infrared radiation at a wavelength of at least 800 nm and up to and including 850 nm or at least 1060 and up to and including 1120 nm.

The imaging apparatus can be configured as a flatbed recorder or as a drum recorder, with the lithographic printing plate precursor mounted to the interior or exterior cylindrical surface of the drum. An example of an useful imaging apparatus is available as models of Kodak® Trendsetter platesetters available from Eastman Kodak Company that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from DiaNippon, Chicago, Ill.).

Imaging of the lithographic printing plate precursor with infrared radiation can be carried out generally at imaging energies (fluence) of at least 500 mJ/cm² and up to and including 5,000 mJ/cm², or in other embodiments a fluence of at least 300 mJ/cm² and up to and including 1,000 mJ/cm² depending upon the sensitivity of the imageable layer. In some embodiments, high imaging fluence is used, for example at a fluence of at least 2,000 mJ/cm² and up to and including 4,000 mJ/cm².

The hydrophobic thermosetting polymeric particles in the imageable layer have a relatively high Tg that is not reached during manufacture of the lithographic printing plate precursor. However, when imaging occurs, the Tg of the curable composition in the particles is usually exceeded so that there is at least partial and perhaps full curing (perhaps melting) in the imageable layer and the hydrophobic thermosetting particles are fused together, but only in the imaged (exposed) regions. These fused or melted particles are also better adhered to the hydrophilic substrate in the exposed regions.

In the non-imaged (non-exposed) regions, the hydrophobic thermosetting particles are not cured (melted or fused) and they can be easily removed during processing (see below). This mechanism for imaging does not rely, like many known precursors, on the presence of a film-forming polymeric binder to hold the hydrophobic thermosetting particles in place in the imageable layer. Thus, the hydrophobic thermosetting polymeric particles used in this invention are more easily and efficiently bonded and fused during imaging in the exposed regions and easily removed in the non-exposed regions without the presence of a film-forming polymeric binder. In addition, the exposed regions of the imageable layer exhibit good adhesion to the hydrophilic substrate (or underlying hydrophilic layer) and provide improved print run length.

After imagewise exposure of the lithographic printing plate precursor, it can be processed off-press in a simple manner without using an alkaline processing solution (developer), or follow up with a gumming (finishing) solution, to remove the non-exposed regions of the imageable layer along with the hydrophobic thermosetting particles in those non-exposed regions. For example, a material such as a wet fabric, cloth, or roller that is wet with water can be used to wipe off the non-exposed regions of the imageable layer.

In other embodiments, processing and removal of non-exposed regions of the imageable layer containing hydrophobic thermosetting particles can be carried out in the absence of (without using) a liquid or wet material only by dry rubbing the imageable layer with a cloth, roller, or other suitable dry article. This can be achieved, for example, by the use of dry brushes or rollers that can be combined with a vacuum system to remove removed debris. Thus, also in these embodiments, the lithographic printing plate is made ready for lithographic printing without using an alkaline processing solution or gumming solution.

In still other embodiments, the non-exposed regions of the imageable layer containing hydrophobic thermosetting particles can be removed on-press using a fountain solution, a lithographic printing ink, or both a fountain solution and a lithographic printing ink.

The purpose of processing after imagewise exposure is to remove the non-exposed regions containing hydrophobic thermosetting particles without affecting the exposed (imaged) regions containing cured (or fused) hydrophobic thermosetting particles. After this processing, the resulting lithographic printing plate can be used immediately for printing.

But in some embodiments, a further post-processing curing can be used to further cure, harden or fuse the hydrophobic thermosetting particles in the exposed regions, and to enhance the adhesion of these particles to each other and to the hydrophilic substrate (or underlying hydrophilic layer). Any means can be used for this “curing”, including but not limited to floodwise exposure to infrared (IR) irradiation, UV irradiation, or heat.

When UV exposure is used, the hydrophobic thermosetting particles can be made UV sensitive by the incorporation of UV sensitizers in the curable composition. Alternatively, the hydrophobic thermosetting polymeric particles are designed to become UV-sensitive upon imagewise exposure. Useful UV sensitizers would be readily apparent to a skilled artisan, and they can be incorporated in an amount of at least 0.1 weight % and up to and including 10 weight %, based on the total dry weight of the hydrophobic thermosetting particles.

Following processing (removal of non-exposed regions in the imageable layer) and optional post-processing curing, the resulting lithographic printing plate can be used for printing without a distinct water rinsing or gumming (finishing) step.

Printing can be carried out by applying a lithographic printing ink and fountain solution to the printing surface of the lithographic printing plate. The fountain solution is taken up by the non-imaged regions, that is, the surface of the hydrophilic substrate revealed by imaging and processing, and the ink is taken up by the imaged (exposed) regions of the imageable layer. The ink is then transferred to a suitable receiving material (such as cloth, paper, metal, glass, or plastic) to provide a desired impression of the image thereon. If desired, an intermediate “blanket” roller can be used to transfer the ink from the lithographic printing plate to the receiving material.

An advantage of the present invention is that the printing surface of the lithographic printing plates has high resistance to a variety of solvents that can be used in the lithographic printing process, either as fountain solution additives or lithographic ink ingredients, or in blanket washes.

The present invention provides at least the following embodiments and combinations thereof, but other combinations of features are considered to be within the present invention as a skilled artisan would appreciate from the teaching of this disclosure:
1. A lithographic printing plate precursor that is sensitive to infrared radiation, the lithographic printing plate precursor comprising:

a hydrophilic substrate,

an imageable layer disposed over the hydrophilic substrate, and

optionally a hydrophilic layer disposed over the hydrophilic substrate and under the imageable layer,

the imageable layer consisting essentially of hydrophobic thermosetting particles that comprise: (1) a curable composition that has a softening point of at least 50° C. and up to and including 120° C. as determined by ASTM D6493, and a curing temperature of at least 150° C. and up to and including 250° C. as determined by Differential Scanning Calorimetry (DSC) at a heating rate of 10° C./minute, and optionally (2) one or more pigments in an amount of less than 30 weight % based on the total dry weight of the hydrophobic thermosetting particles,

wherein the curable composition comprises a polymerizable oligomer comprising one or more reactive epoxy, hydroxy, carboxyl, or amino groups, and

wherein prior to infrared radiation exposure:
(a) the hydrophobic thermosetting particles adhere to each other and to the substrate such that at least 65 weight % of the hydrophobic thermosetting particles are retained on the substrate when subjected to an air blowing test,
(b) at least 90 weight % of the hydrophobic thermosetting particles can be removed from the imageable layer by dry rubbing using a dry woven cloth having at least 90% cotton in the direction of the graining using manual pressure for 30 seconds, and
(c) the hydrophobic thermosetting particles have an average diameter of at least 1 μm.
2. The precursor of embodiment 1 wherein, prior to infrared radiation exposure, the hydrophobic thermosetting particles have an average diameter of at least 1 μm and up to and including 20 μm.
3. The precursor of embodiment 1 or 2 wherein, prior to infrared radiation exposure, the hydrophobic thermosetting particles have an average diameter of at least 1 μm and up to and including 5 μm.
4. The precursor of any of embodiments 1 to 3 wherein, the lithographic printing plate precursor comprises an aluminum-containing substrate and a hydrophilic layer disposed between the aluminum-containing substrate and the imageable layer.
5. The precursor of any of embodiments 1 to 4 wherein, the hydrophobic thermosetting particles comprise one or more pigments at least one of which is a carbon black that is present in an amount of at least 0.1 weight % and up to and including 30 weight % based on the total dry weight of the hydrophobic thermosetting particles.
6. The precursor of any of embodiments 1 to 5 wherein, the hydrophobic thermosetting particles comprise a curable composition that has a softening point of at least 50° C. and up to and including 80° C. as determined by ASTM D6493, and a curing temperature of at least 150° C. and up to and including 200° C. as determined by DSC at a heating rate of 10° C./minute.
7. The precursor of any of embodiments 1 to 6 wherein, the polymerizable oligomers is selected from the group consisting of acrylic oligomers, epoxy-containing prepolymers, amino-modified epoxy oligomers, phenolic-modified epoxy oligomers, and combinations of a polyol with an isocyanate-containing oligomer.
8. The precursor of any of embodiments 1 to 7 wherein, the curable composition in the hydrophobic thermosetting particles further comprises a curing agent for the polymerizable oligomer.
9. The precursor of any of embodiments 1 to 8 wherein, the imageable layer comprises an infrared radiation absorber only in the hydrophobic thermosetting particles.
10. The precursor of any of embodiments 1 to 9 that is sensitive to infrared radiation, and comprises a hydrophilic aluminum-containing substrate.
11. A method of making a lithographic printing plate, the method comprising:

imagewise exposing the lithographic printing plate precursor of any of embodiments 1 to 10 to infrared radiation, to create exposed and non-exposed regions in the imageable layer, and

removing the hydrophobic thermosetting particles in the non-exposed regions of the imageable layer.
12. The method of embodiment 11 further comprising, after removing the hydrophobic thermosetting particles in the non-exposed regions of the imageable layer, exposing the lithographic printing plate to heat or UV irradiation.
13. The method of embodiment 11 or 12 comprising, imagewise exposing the lithographic printing plate precursor using energy of at least 500 mJ/cm² and up to and including 5,000 mJ/cm².
14. The method of embodiment 11 or 12 comprising, imagewise exposing the lithographic printing plate precursor using energy of at least 300 mJ/cm² and up to and including 1,000 mJ/cm².
15. The method of any of embodiments 11 to 14 wherein, the removing of the hydrophobic thermosetting particles in the non-exposed regions of the imageable layer is carried out on-press using a fountain solution, lithographic printing ink, or both fountain solution and lithographic printing ink.
16. The method of any of embodiments 11 to 14 wherein, the removing of the hydrophobic thermosetting particles in the non-exposed regions of the imageable layer is carried out using a wet material.
17. The method of any of embodiments 11 to 14 wherein, the removing of the hydrophobic thermosetting particles in the non-exposed regions of the imageable layer is carried out without using a liquid or wet material.
18. The method of any of embodiments 11 to 14 or 17 wherein, the removing of the hydrophobic thermosetting particles in the non-exposed regions of the imageable layer is carried out using only dry rubbing of the imageable layer.
19. The method of any of embodiments 11 to 14, 17, or 18 wherein, the lithographic printing plate is made without using an alkaline processing solution or gumming solution.
20. A method of preparing the lithographic printing plate precursor or any of embodiments 1 to 10, comprising:

applying a suspension of hydrophobic thermosetting particles over a hydrophilic substrate, the hydrophobic thermosetting particles comprising: (1) a curable composition that has a softening point of at least 70° C. and up to and including 120° C. as determined by ASTM D6493, and a curing temperature of at least 150° C. and up to and including 250° C. as determined by Differential Scanning Calorimetry (DSC) at a heating rate of 10° C./minute, and optionally (2) one or more pigments in an amount of less than 30 weight % based on the total dry weight of the hydrophobic thermosetting particles,

wherein the curable composition comprises a polymerizable oligomer comprising one or more reactive epoxy, hydroxy, carboxyl, or amino groups, and

wherein prior to infrared radiation exposure:
(a) the hydrophobic thermosetting particles adhere to each other and to the substrate such that at least 65 weight % of the hydrophobic thermosetting particles are retained on the substrate when subjected to an air blowing test,
(b) at least 80 weight % of the hydrophobic thermosetting particles can be removed from the imageable layer by dry rubbing using a dry woven cloth having at least 90% cotton in the direction of the graining using manual pressure for 30 seconds, and
(c) the hydrophobic thermosetting particles have an average diameter of at least 1 μm,

optionally applying a hydrophilic layer formulation over the substrate to form a hydrophilic layer prior to applying the suspension of hydrophobic thermosetting particles over the hydrophilic layer, and

drying the suspension of hydrophobic thermosetting particles to form a dried imageable layer on the hydrophilic substrate to form an imageable layer.
21. The method of embodiment 20 comprising, drying the suspension of hydrophobic thermosetting particles at a temperature of at least 55° C. for at least 30 seconds.
22. The method of embodiment 20 or 21 wherein, the curable composition in the hydrophobic thermosetting particles further comprises a curing agent for the polymerizable oligomer.
23. The method of any of embodiments 20 to 22 wherein the suspension of hydrophobic thermosetting particles is an aqueous suspension that comprises less than 5 weight % of a water-soluble or water-dispersible binder.

The following Examples are provided to illustrate the practice of this invention and are not meant to be limiting in any manner.

During imaging, a lithographic printing plate precursor as described above was imaged in a Kodak® Trendsetter computer-to-plate imager using an energy (fluence) of at least 300 and up to and including 1000 mJ/cm², and typically of at least 500 and up to and including 700 mJ/cm².

The lithographic printing plates were tested for solvent resistance. The solvents used for this test were an 80/20 mixture of Butyl Cellosolve and water and an 80/20 mixture of diacetone alcohol and water. Also used for the test were Heat-Set Fountain solutions typically used in offset lithographic printing and a blanket wash used for UV litho inks that are based on mixtures of glycol ethers. The solvent resistance tests were carried out in the following manner:
1. One drop of solvent solution was applied from a 3 ml pipette onto a 50% screen that had been imaged and developed on a sample of the lithographic printing plate precursor used in the present invention.
2. The drop of solvent solution was allowed to soak into the surface of the image for twenty minutes before being removed with a cloth.
3. The area where the solvent solution drop had been placed was rubbed with a dry cloth and the image then visually examined. There should be no visible damage where the drop had been for the coating to be pronounced solvent resistant for purposes of this invention.

In the following Examples, all quantities are given in parts by weight. The following hydrophilic layer formulation was prepared by dissolving the noted components in the order shown in water, in the amounts shown.

Hydrophilic Layer 1:

Tetraethoxy silane (525 parts)

Colloidal silica suspension (30% solids) (5,250 parts)

Water (10,000 parts).

This formulation was coated onto an electrochemically grained and anodized aluminum substrate using a #0 wire wound coating rod and the water was evaporated in an oven for 10 minutes at 120° C., providing a dry coating thickness of 0.5 μm to form a dry hydrophilic layer.

Hydrophilic Layer 2:

Poly(vinyl alcohol) (425 parts)

Colloidal silica (30% solids) (375 parts)

Glyoxal (75 parts)

Water (10,000 parts).

This formulation was coated onto an electrochemically grained and anodized aluminum substrate using a #3 wire wound coating rod and the water was evaporated in an oven for 4 minutes at 140° C., providing a dry coating thickness of 1 μm to form a dry hydrophilic layer.

### INVENTION EXAMPLE 1

An imageable layer formulation was prepared using 510 grams of a Fusion Bonded Epoxy powder (containing thermosetting polymer, polymerizable oligomer, and a carbon black) that was poured into 1000 grams of water containing 10 g of Triton® X100 nonionic surfactant. The resulting imageable layer formulation was coated onto Hydrophilic Layer 1 described above using a number #0 rod and the coating was dried at 80° C. for 2 minutes to provide a dry infrared radiation-sensitive imageable layer having a 1.3 μm dry thickness.

A sample of the resulting lithographic plate precursor was then imaged on a Kodak® Trendsetter imagesetter at a fluence (energy) of 1000 mJ/cm². The imaged precursor was then dry processed by rubbing and floodwise exposed to a source of infrared radiation. The resulting lithographic printing plates were then tested as described above and found to exhibit the desired solvent resistance. The lithographic plate precursors were then placed on a printing press and used to produce good quality impressions.

### INVENTION EXAMPLE 2

An imageable layer formulation was prepared by pouring 480 grams of a powder used in the Fusion Bonding Epoxy powder (described above) into 1000 grams of water containing 10 g of Triton® X100 nonionic surfactant. This imageable layer formulation was coated onto Hydrophilic Layer 2 described above using a number #0 rod and dried at 80° C. for 2 minutes to provide a infrared radiation-sensitive imageable layer of a 1.3 μm dry thickness.

Samples of the resulting lithographic printing plate precursor were then imaged on a Kodak® Trendsetter imagesetter at a fluence (energy) of 4000 mJ/cm². The imaged precursor was then processing using water and placed on a printing press and used to produce good quality impressions.

### INVENTION EXAMPLE 3

Epoxy-polyester powder (48 g, FN6014 from Akzo Nobel) was poured into 100 grams of water containing 1.1 g of Triton® X100 nonionic surfactant. The epoxy-polyester powder particles had a particle size of d(0.5)=6.328 and contained 0.7 weight % carbon black. The suspension was applied to Hydrophilic Layer 1 using a rod at a 10 μm wet coating coverage and the coating was dried at 75° C. for 2 minutes to provide an infrared radiation-sensitive imageable layer having a 3.2 μm dry thickness.

The resulting lithographic printing plate precursor was then imaged on a Kodak® Trendsetter imagesetter at a fluence of (600-3000) mJ/cm² in steps of 300 mJ/cm². After removal from the imagesetter, the imaged precursor was heated for 10 minutes at 170° C., processed (developed) with water, and placed on a printing press where at least 50,000 good impressions were made. The lithographic printing plate exhibited good resistance to 80 weight % BC (butyl cellulose:water), 80 weight % DAA (diacetone alcohol:water), and an aggressive alcohol sub fount E9069 product.

### INVENTION EXAMPLE 4

A suspension of particles of a UV powder (LG64442, 48 g), 100 g of water, and 1.1 g of Triton® X100 nonionic surfactant was milled for 2 weeks using a ball mill. The LG64442 particles contained (meth)acrylated epoxy/polyester resin, Irgacure® 2959 curing agent, and Irgacure® 819 curing agent, and 0.6 weight % of carbon black. The milled formulation was coated onto Hydrophilic Layer 1 using a rod at a 10 μm wet coating weight and the coating was dried at 75° C. for 2 minutes to provide an imageable layer having a dry thickness of 3.2 μm.

The resulting lithographic printing plate precursor was then imaged on a Kodak® Trendsetter imagesetter at a fluence of (900-3000) mJ/cm² in steps of 300 mJ/cm². After removal from the imagesetter, the imaged precursor was heated on a hot plate for 18 seconds and then exposed to blanket UV radiation. The imaged precursor was then processed using water and placed on a printing press where good impressions were made.

### INVENTION EXAMPLE 5

Epoxy-based particles containing 80 weight % of an epoxy resin, 8 weight % of an amine oligomer hardener, 2 weight % of 2-methyl imidazole as curing accelerator, and 10 weight % of carbon black was coated in dry form over a grained and anodized aluminum substrate that had been coated with Hydrophilic Layer 1. The resulting lithographic printing plate precursor was heated for 2 minutes at 80° C. and could be handled without damaging the resulting imageable layer.

The lithographic printing plate was imaged on a Kodak® Trendsetter imagesetter at a fluence of either 1000 mJ/cm² or 2000 mJ/cm². The non-exposed regions were processed (developed) by dry rubbing. The exposed regions could not be removed by rubbing and a clear image remained on each lithographic printing plate that was put onto a printing press to provide a clean background and a clear image.

The invention has been described in detail with particular reference to certain preferred embodiments thereof, but it will be understood that variations and modifications can be effected within the spirit and scope of the invention.

1. A lithographic printing plate precursor that is sensitive to infrared radiation, the lithographic printing plate precursor comprising:
a hydrophilic substrate,
an imageable layer disposed over the hydrophilic substrate, and
optionally a hydrophilic layer disposed over the hydrophilic substrate and under the imageable layer,
the imageable layer consisting essentially of hydrophobic thermosetting particles that comprise: (1) a curable composition that has a softening point of at least 50° C. and up to and including 120° C. as determined by ASTM D6493, and a curing temperature of at least 150° C. and up to and including 250° C. as determined by Differential Scanning Calorimetry (DSC) at a heating rate of 10° C./minute, and optionally (2) one or more pigments in an amount of less than 30 weight % based on the total dry weight of the hydrophobic thermosetting particles,
wherein the curable composition comprises a polymerizable oligomer comprising one or more reactive epoxy, hydroxy, carboxyl, or amino groups, and
wherein prior to infrared radiation exposure:
(a) the hydrophobic thermosetting particles adhere to each other and to the substrate such that at least 65 weight % of the hydrophobic thermosetting particles are retained on the substrate when subjected to an air blowing test,
(b) at least 90 weight % of the hydrophobic thermosetting particles can be removed from the imageable layer by dry rubbing using a dry woven cloth having at least 90% cotton in the direction of the graining using manual pressure for 30 seconds, and
(c) the hydrophobic thermosetting particles have an average diameter of at least 1 μm.

2. The precursor of claim 1 wherein, prior to infrared radiation exposure, the hydrophobic thermosetting particles have an average diameter of at least 1 μm and up to and including 20 μm.

3. The precursor of claim 1 wherein, prior to infrared radiation exposure, the hydrophobic thermosetting particles have an average diameter of at least 1 μm and up to and including 5 μm.

4. The precursor of claim 1 wherein the lithographic printing plate precursor comprises an aluminum-containing substrate and a hydrophilic layer disposed between the aluminum-containing substrate and the imageable layer.

5. The precursor of claim 1 wherein the hydrophobic thermosetting particles comprise one or more pigments at least one of which is a carbon black that is present in an amount of at least 0.1 weight % and up to and including 30 weight % based on the total dry weight of the hydrophobic thermosetting particles.

6. The precursor of claim 1 wherein the hydrophobic thermosetting particles comprise a curable composition that has a softening point of at least 50° C. and up to and including 80° C. as determined by ASTM D6493, and a curing temperature of at least 150° C. and up to and including 200° C. as determined by DSC at a heating rate of 10° C./minute.

7. The precursor of claim 1, wherein the polymerizable oligomers is selected from the group consisting of acrylic oligomers, epoxy-containing prepolymers, amino-modified epoxy oligomers, phenolic-modified epoxy oligomers, and combinations of a polyol with an isocyanate-containing oligomer.

8. The precursor of claim 1 wherein the curable composition in the hydrophobic thermosetting particles further comprises a curing agent for the polymerizable oligomer.

9. The precursor of claim 1 wherein the imageable layer comprises an infrared radiation absorber only in the hydrophobic thermosetting particles.

10. A lithographic printing plate precursor that is sensitive to infrared radiation, the lithographic printing plate precursor comprising:
a hydrophilic aluminum-containing substrate,
an imageable layer disposed over the hydrophilic substrate, and
optionally a hydrophilic layer disposed over the hydrophilic aluminum-containing substrate and under the imageable layer,
the imageable layer consisting essentially of hydrophobic thermosetting particles that comprise: (1) a curable composition that has a softening point of at least 50° C. and up to and including 80° C. as determined by ASTM D6493, and a curing temperature of at least 150° C. and up to and including 200° C. as determined by Differential Scanning Calorimetry (DSC) at a heating rate of 10° C./minute, and (2) a carbon black in an amount of at least 0.1 weight % and up to and including 20 weight % based on the total dry weight of the hydrophobic thermosetting particles,
wherein the curable composition comprises a polymerizable oligomer selected from the group consisting of acrylic oligomers, epoxy-containing prepolymers, amino-modified epoxy oligomers, phenolic-modified epoxy oligomers, and a polyol with an isocyanate-containing oligomer, and the curable composition also comprises a curing agent for the curable composition, the imageable layer containing less than 5 weight % of film-forming binder polymers,
wherein prior to infrared radiation exposure:
(a) the hydrophobic thermosetting particles adhere to each other and to the substrate such that at least 80 weight % of the hydrophobic thermosetting particles are retained on the substrate when subjected to an air blowing test,
(b) at least 90 weight % of the hydrophobic thermosetting particles can be removed from the imageable layer by dry rubbing using a dry woven cloth having at least 90% cotton in the direction of the graining using manual pressure for 30 seconds, and
(c) the hydrophobic thermosetting particles have an average diameter of at least 1 μm and up to and including 10 μm.

11. A method of making a lithographic printing plate, the method comprising:
imagewise exposing the lithographic printing plate precursor of claim 1 to infrared radiation, to create exposed and non-exposed regions in the imageable layer, and
removing the hydrophobic thermosetting particles in the non-exposed regions of the imageable layer.

12. The method of claim 11 further comprising, after removing the hydrophobic thermosetting particles in the non-exposed regions of the imageable layer, exposing the lithographic printing plate to heat or UV irradiation.

13. The method of claim 11 comprising, imagewise exposing the lithographic printing plate precursor using energy of at least 500 mJ/cm² and up to and including 5,000 mJ/cm².

14. The method of claim 11 comprising, imagewise exposing the lithographic printing plate precursor using energy of at least 300 mJ/cm² and up to and including 1,000 mJ/cm².

15. The method of claim 11 wherein, the removing of the hydrophobic thermosetting particles in the non-exposed regions of the imageable layer is carried out on-press using a fountain solution, lithographic printing ink, or both fountain solution and lithographic printing ink.

16. The method of claim 11 wherein, the removing of the hydrophobic thermosetting particles in the non-exposed regions of the imageable layer is carried out using a wet material.

17. The method of claim 11 wherein, the removing of the hydrophobic thermosetting particles in the non-exposed regions of the imageable layer is carried out without using a liquid or wet material.

18. The method of claim 11 wherein, the removing of the hydrophobic thermosetting particles in the non-exposed regions of the imageable layer is carried out using only dry rubbing of the imageable layer.

19. The method of claim 11 wherein, the lithographic printing plate is made without using an alkaline processing solution or gumming solution.

20. A method of making a lithographic printing plate, the method comprising:
imagewise exposing the lithographic printing plate precursor of claim 10 to infrared radiation, to create exposed and non-exposed regions in the imageable layer, and
removing the hydrophobic thermosetting particles in the non-exposed regions of the imageable layer.

21. A method of preparing a lithographic printing plate precursor, comprising:
applying a suspension of hydrophobic thermosetting particles over a hydrophilic substrate, the hydrophobic thermosetting particles comprising: (1) a curable composition that has a softening point of at least 70° C. and up to and including 120° C. as determined by ASTM D6493, and a curing temperature of at least 150° C. and up to and including 250° C. as determined by Differential Scanning Calorimetry (DSC) at a heating rate of 10° C./minute, and optionally (2) one or more pigments in an amount of less than 30 weight % based on the total dry weight of the hydrophobic thermosetting particles,
wherein the curable composition comprises a polymerizable oligomer comprising one or more reactive epoxy, hydroxy, carboxyl, or amino groups, and
wherein prior to infrared radiation exposure:
(a) the hydrophobic thermosetting particles adhere to each other and to the substrate such that at least 65 weight % of the hydrophobic thermosetting particles are retained on the substrate when subjected to an air blowing test,
(b) at least 80 weight % of the hydrophobic thermosetting particles can be removed from the imageable layer by dry rubbing using a dry woven cloth having at least 90% cotton in the direction of the graining using manual pressure for 30 seconds, and
(c) the hydrophobic thermosetting particles have an average diameter of at least 1 μm,
optionally applying a hydrophilic layer formulation over the substrate to form a hydrophilic layer prior to applying the suspension of hydrophobic thermosetting particles over the hydrophilic layer, and
drying the suspension of hydrophobic thermosetting particles to form a dried imageable layer on the hydrophilic substrate to form an imageable layer.

22. The method of claim 21 wherein, before drying, the hydrophobic thermosetting particles have an average diameter of at least 1 μm and up to and including 10 μm.

23. The method of claim 21 comprising, drying the suspension of hydrophobic thermosetting particles at a temperature of at least 55° C. for at least 30 seconds.

24. The method of claim 21 wherein, the curable composition in the hydrophobic thermosetting particles further comprises a curing agent for the polymerizable oligomer.

25. The method of claim 21 wherein the suspension of hydrophobic thermosetting particles is an aqueous suspension that comprises less than 5 weight % of a water-soluble or water-dispersible binder.
